(19) United States
(12) Patent Application Publication
(10) Pub. No.: US 2025/0248214 A1
(43) Pub. Date: Jul. 31, 2025

(54) Array Substrate and Manufacturing Method Therefor, and Display Apparatus

(71) Applicant: Truly (Huizhou) Smart Display Limited, Huizhou City (CN)

(72) Inventors: Jinzhao Luo, Huizhou City (CN); Junwen Hu, Huizhou City (CN)

(21) Appl. No.: 18/702,192

(22) PCT Filed: Nov. 23, 2021
(86) PCT No.: PCT/CN2021/132581

§ 371 Date: Jun. 14, 2024

(30) Foreign Application Priority Data
Oct. 18, 2021 (CN) 202111211859.3

(51) Int. Cl. H10K 59/121; H10K 59/12; H10K 59/126

(52) U.S. Cl. CPC H10K 59/1213; H10K 59/1201; H10K 59/126

(57) ABSTRACT

The present invention relates to an array substrate, comprising: a base substrate, which is provided with a first area and a second area, which are parallel to each other; a first transistor, which is located in the first area and is provided with a first active layer, wherein the first active layer is low-temperature polycrystalline silicon; a second transistor, which is located in the second area and is provided with a second active layer, wherein the second active layer is a metal oxide semiconductor; a first light-shielding layer, which is arranged right below the second active layer, wherein at least an interlayer dielectric layer is provided between the first light-shielding layer and the second active layer; and a second light-shielding layer, which is arranged right above the second active layer, wherein a planarization layer and a fifth insulating layer are provided between the second light-shielding layer and the second active layer. The present invention also relates to a method for preparing the array substrate. The present invention also relates to a display apparatus, comprising the array substrate.

### FIELD OF THE DISCLOSURE

The present disclosure relates to the technical field of displaying, and in particular, to an array substrate and a manufacturing method thereof, and a display apparatus.

### BACKGROUND OF THE DISCLOSURE

At present, an active matrix organic light emitting diode (AMOLED) display screen is widely used in smartphones due to its wider viewing angle, higher refresh rate, and smaller size. However, the power consumption of the AMOLED display screen is high. In order to solve the problem of high power consumption of the AMOLED display screen while maintaining the high refresh rate, the existing technical solution is to use a low temperature polycrystalline oxide (LTPO) technology to manufacture a pixel driver circuit for an AMOLED driver backboard. The LTPO technology combines the advantages of two kinds of thin film transistors (TFTs): a low temperature polysilicon thin film transistor (LTPS-TFT) and an oxide-TFT. That is, the LTPO technology combines the high mobility of the LTPS-TFT and the low leakage current of the oxide-TFT. Therefore, the LTPO technology is used to manufacture a switch transistor in the pixel driver circuit, which can achieve free switching between a low refresh rate and a high refresh rate of the AMOLED display screen and reduce the power consumption of the display screen. Therefore, the LTPO technology has certain technological advantages in high pixels per inch (PPI), low power consumption, and the high image quality of the AMOLED display screen.

The existing LTPO technology includes: simultaneously preparing a LTPS-TFT and a metal oxide-TFT on an array substrate. However, the application of the LTPO technology in the AMOLED display screen has the following technical problems:

1. The oxide-TFT is very sensitive to light. An active layer (a metal oxide semiconductor) of the oxide-TFT would generate a certain amount of photon-generated carriers inside its material under a light condition, leading to an increase in the leakage current, a shift in threshold voltage (Vth), and degradation of characteristics of the oxide-TFT.

2. Due to the self-illumination of the AMOLED display screen, light emitted by an OLED is inevitably reflected or refracted. Irradiated by external incident light, the oxide-TFT is inevitably exposed to light, which leads to the degradation of the metal oxidation characteristics of the active layer (the metal oxide semiconductor) of the oxide-TFT. This affects the display effect and the display reliability.

### SUMMARY OF THE INVENTION

The present disclosure aims to provide an array substrate and a manufacturing method thereof, and a display apparatus, thus at least solving, to a certain extent, one or more problems caused by the limitation and defects of the related technology.

Other features and advantages of the present disclosure will become clear through the detailed description below, or partially learned through the practice of the present disclosure.

According to one aspect of the present disclosure, an array substrate is provided, including:
a base substrate, wherein the base substrate is provided with a first region and a second region which are juxtaposed;
a first transistor, wherein the first transistor is located in the first region; the first transistor is provided with a first active layer, and the first active layer is low temperature polycrystalline silicon (LTPS); a buffer layer is arranged between the first active layer and an upper surface of the base substrate; the first transistor is further provided with a first gate layer; a first insulating layer is arranged between the first gate layer and an upper surface of the first active layer; a source-drain electrode layer of the first transistor is electrically connected to two ends of the first active layer through two through holes respectively;
a second transistor, wherein the second transistor is located in the second region; the second transistor is provided with a second active layer, and the second active layer is a metal oxide semiconductor; the second transistor is further provided with a second gate layer and a third gate layer; a third insulating layer is arranged between the second gate layer and a lower surface of the second active layer; a fourth insulating layer is arranged between the third gate layer and an upper surface of the second active layer; a source-drain electrode layer of the second transistor is electrically connected to two ends of the second active layer through two through holes respectively;
a first light-shielding layer, wherein the first light-shielding layer is arranged right below the second active layer, and at least an interlayer dielectric layer is arranged between the first light-shielding layer and the second active layer; and
a second light-shielding layer, wherein the second light-shielding layer is arranged right above the second active layer, and a planarization layer and a fifth insulating layer are arranged between the second light-shielding layer and the second active layer.

A width of the first light-shielding layer and a width of the second light-shielding layer are not less than a width of the second active layer. More specifically, when observed in a direction perpendicular to the second active layer, the first light-shielding layer will completely cover the upper surface of the second active layer, and the second light-shielding layer will completely cover the lower surface of the second source layer.

The second light-shielding layer is formed by partially etching an organic light emitting diode (OLED) anode layer. A composition of the OLED anode layer is indium tin oxide layer (ITO)/silver layer (AG)/indium tin oxide layer (ITO).

In an embodiment, the first light-shielding layer is formed by partially etching the first gate layer. A material of the first gate layer is one or a mixture of several of molybdenum and its alloy, chromium and its alloy, aluminum and its alloy, copper and its alloy, and titanium and its alloy.

In an embodiment, the first light-shielding layer is the second gate layer.

In a second aspect, the present disclosure provides a method for manufacturing the aforementioned array substrate, including:
forming the first transistor on the first region of the base substrate by performing a composition process for multiple times, wherein the first transistor is provided the first active layer, and the first active layer is the LTPS; forming a second transistor above the first insulating layer located in the second region by performing the composition process for multiple times, wherein the second transistor is provided with the second active layer, and the second active layer is the metal oxide semiconductor;
during the formation of the first gate layer of the first transistor, depositing a metal layer on an upper surface of the first insulating layer, and partially etching the metal layer to obtain the first gate layer located in the first region and the first light-shielding layer located in the second region;
after coating the formed first and second transistors with the planarization layer, depositing an ITO layer, an AG layer, and an ITO layer in sequence on an upper surface of the planarization layer; and then performing a photolithography technique on the stacked metal layer to obtain the OLED anode layer located in the first region and the second light-shielding layer located in the second region.

In a third aspect, the present disclosure provides a method for manufacturing the aforementioned array substrate, including:
forming the first transistor on the first region of the base substrate by performing a composition process for multiple times, wherein the first transistor is provided the first active layer, and the first active layer is the LTPS; forming a second transistor above the first insulating layer located in the second region by performing the composition process for multiple times, wherein the second transistor is provided with the second active layer, and the second active layer is the metal oxide semiconductor;
depositing a second insulating layer after forming the first gate layer of the first transistor, wherein the second insulating layer further extends to the second region of the base substrate; depositing a metal layer on an upper surface of the second insulating layer; partially etching the metal layer to obtain a capacitor upper electrode layer located in the first region and the first light-shielding layer located in the second region;
after coating the formed first and second transistors with the planarization layer, depositing an ITO layer, an AG layer, and an ITO layer in sequence on an upper surface of the planarization layer; and then performing a photolithography technique on the stacked metal layer to obtain the OLED anode layer located in the first region and the second light-shielding layer located in the second region.

In a fourth aspect, the present disclosure provides a display apparatus, including the aforementioned array substrate.

According to the array substrate of some embodiments of the present disclosure, the first light-shielding layer and the second light-shielding layer are included, and the metal oxide semiconductor of the second transistor is located between the first light-shielding layer and the second light-shielding layer, so that the first light-shielding layer and the second light-shielding layer act as light barriers to the metal oxide semiconductor, which can prevent the negative impact of light emitted by subsequent OLEDs and external incident light on the metal oxide semiconductor, thus preventing the adverse effects on the transistor characteristics of the second transistor. The second light-shielding layer is mainly used to block diffracted light during light emission of the OLED from illuminating the metal oxide semiconductor, and the first light-shielding layer is used to block light projected from a surface of the base substrate from illuminating the metal oxide semiconductor.

It should be understood that the foregoing general descriptions and the following detailed descriptions are merely for illustration and explanation purposes and are not intended to limit the present disclosure.

The present disclosure will be explained below with reference to specific embodiments.

### BRIEF DESCRIPTION OF THE DRAWINGS

The accompanying drawings are intended to provide a further explanation of the present disclosure, but the embodiments in the accompanying drawings will not constitute any limitation on the present disclosure.

FIG. 1 is a schematic structural diagram of an array substrate provided according to Embodiment 1 of the present disclosure; and

FIG. 2 is a schematic structural diagram of an array substrate provided according to Embodiment 2 of the present disclosure.

### REFERENCE NUMERALS IN THE DRAWINGS

01: base substrate;
02: buffer layer;
03: LTPS layer;
04: first insulating layer;
051: first gate layer;
052: first light-shielding layer;
06: second insulating layer;
071: capacitor upper electrode layer;
072: second gate layer;
08: third insulating layer;
09: metal oxide semiconductor layer;
10: fourth insulating layer;
11: third gate layer;
12: fifth insulating layer;
131: first via hole;
132: second via hole;
141: source-drain electrode layer of first transistor;
142: source-drain electrode layer of second transistor;
15: planarization layer;
151: planarization layer via hole;
161: OLED anode layer;
162: second light-shielding layer;
171: pixel definition layer;
172: supporting column layer;
18: OLED luminescent layer;
19: OLED cathode layer;
20: thin film encapsulation layer;
A1: first region; and
A2: second region.

### DETAILED DESCRIPTION OF THE EMBODIMENTS

The exemplary implementations will be described more comprehensively now with reference to the accompanying drawings. However, the exemplary implementations can be implemented in various forms and should not be understood as being limited to the examples described herein. On the contrary, providing these implementations will make the present disclosure more comprehensive and complete, and will comprehensively convey the concept of the exemplary implementations to those skilled in the art. The accompanying drawings are only exemplary illustrations of the present disclosure and may not necessarily be drawn to scale. The same reference numerals in the drawings represent the same or similar parts, so their repeated descriptions will be omitted.

In addition, the features, structures, or characteristics described can be combined in any suitable way in one or more implementations. In the following description, many specific details are provided to provide a full understanding of the implementations of the present disclosure. However, those skilled in the art will realize that one or more of the specific details can be omitted by practicing the technical solutions of the present disclosure, or other methods, components, apparatuses, steps, and the like may be employed. In other cases, failure to detail or describe well-known structures, methods, apparatuses, implementations, materials, or operations may obscure the various aspects of the present disclosure.

Some block diagrams shown in the accompanying diagrams are functional entities and may not necessarily correspond to physically or logically independent entities. These functional entities can be implemented in software form, or in one or more hardware modules or integrated circuits, or in different networks and/or processor apparatuses and/or microcontroller apparatuses.

In addition, the terms “first” and “second” in the present disclosure are used for descriptive purposes only and are not to be construed as indicating or implying relative importance or to implicitly indicate the number of technical features indicated. Thus, features defined as “first” and “second” explicitly or implicitly include one or more of the features. In the description of the present disclosure, “plurality” means two or more, unless otherwise expressly and specifically defined.

It should be noted that the base substrate described in Embodiment 1 and Embodiment 2 can be either a glass substrate or a flexible substrate, and the metal oxide semiconductor layer described in Embodiment 1 and Embodiment 2 is specifically indium gallium zinc oxide.

### Embodiment 1

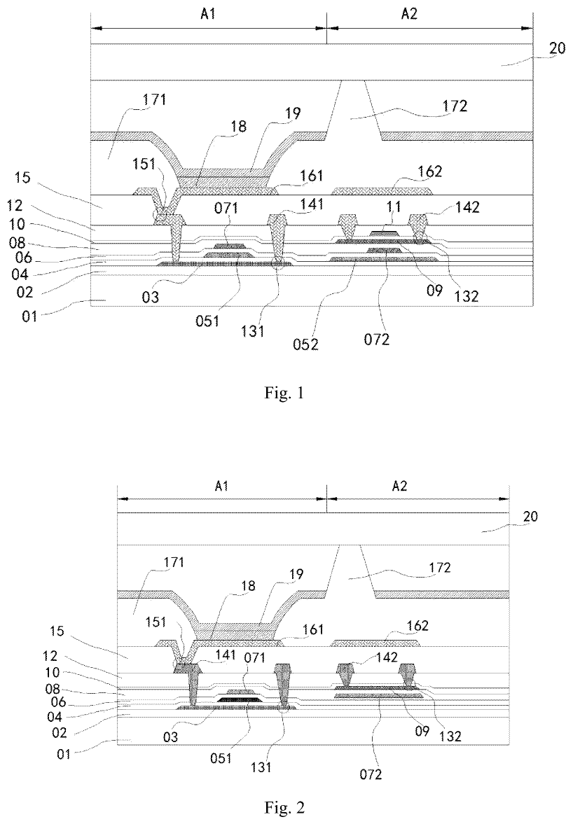

FIG. 1 is a schematic diagram of an array substrate provided according to an exemplary embodiment of the present disclosure. As shown in FIG. 1, the array substrate includes: a base substrate 01, a first transistor arranged in a first region A1 of the base substrate 01, and a second transistor arranged in a second region A2 of the base substrate 01. The first transistor is provided with a first active layer, and the first active layer is a LTPS layer 03, that is, the first transistor is a low temperature polycrystalline silicon thin film transistor (hereinafter referred to as LTPS-TFT). The second transistor is provided with a second active layer, and the second active layer is a metal oxide semiconductor layer 09, that is, the second transistor is an oxide thin film transistor (hereinafter referred to as oxide-TFT).

It should be noted that in this embodiment, there is no detailed introduction to the division of a boundary between the first region and the second region, and this is not the focus of the design of the present disclosure. Labeling of the first region and the second region is only to illustrate that the LTPS-TFT and the oxide-TFT are arranged in different regions. The LTPS-TFT is usually used as a switch transistor due to its fast switching, and the oxide-TFT is usually used as a driver transistor due to its semiconductor characteristics. Further, due to their different characteristics and functions, the two kinds of TFTs need to be arranged separately in the corresponding regions, which has a better effect than the single LTPS-TFT and the single oxide-TFT. The high electron mobility of an LTPS leads to extremely high power consumption. The advantages of the two kinds of TFTs are maximized by combining the low power consumption of oxides and the advantages of the LTPS.

As shown in FIG. 1, structures of the first transistor include: a buffer layer 02, a LTPS layer 03 (namely, the first active layer), a first insulating layer 04, and a first gate layer 051 which are formed on the base substrate 01 in sequence. A source-drain electrode layer 141 of first transistor is electrically connected to two ends of the LTPS layer 03 through two first via holes 131 respectively, and the structure and processing technology of the first transistor have no difference from the existing LTPS-TFT. However, in this embodiment, a capacitor upper electrode layer 071 is also arranged above the first gate layer 051, and a second insulating layer 06 is arranged between the first gate layer 051 and the capacitor upper electrode layer 071. The second insulating layer 06 can be a single-layer silicon oxide (SiOₓ) film or a double-layer film including a silicon nitride (SiNₓ) and a silicon oxide (SiOₓ).

The LTPS layer 03 uses polycrystalline silicon (P-Si), and its formation process can be achieved by using an excimer laser crystallization (ELA) technology to apply a high-power laser beam to a surface of amorphous silicon (a-Si) thin film to be crystallized. Due to the high ultraviolet light absorption ability of silicon, the surface of the amorphous silicon thin film can reach a high temperature of over 1000° C. within very short time (50-150 ns), and the amorphous silicon thin film becomes a molten state. After a laser pulse stops, the molten amorphous silicon is cooled and crystallized into polycrystalline silicon. In order to prevent the laser beam from damaging the base substrate 01, the buffer layer 02 is arranged on the base substrate 01. The buffer layer 02 can be a single-layer silicon oxide (SiOₓ) film or a double-layer film including a silicon nitride (SiNₓ) and a silicon oxide (SiOₓ).

The first insulating layer 04 is a gate insulating layer that covers the LTPS layer 03. It can be a single-layer silicon oxide (SiOₓ) film or a double-layer film including a silicon nitride (SiNₓ) and a silicon oxide (SiOₓ).

As shown in FIG. 1, structures of the second transistor include: a second gate layer 072, a metal oxide semiconductor layer 09, a third gate layer 11, and a source-drain electrode layer 142 of second transistor. The second gate layer 072 serves as a bottom-layer gate electrode located on the second insulating layer 06. A third insulating layer 08 is arranged d between the second gate layer 072 and the metal oxide semiconductor layer 09. The third insulating layer 08 can be a single-layer silicon oxide (SiOₓ) film or a double-layer film including a silicon nitride (SiNₓ) and a silicon oxide (SiOₓ). The third gate layer 11 is arranged as a top-layer gate electrode above the metal oxide semiconductor layer 09, and a fourth insulating layer 10 is arranged between the third gate layer 11 and the metal oxide semiconductor layer 09. The fourth insulating layer 10 is a single-layer silicon oxide (SiOx) film. The source-drain electrode layer 142 of second transistor is electrically connected to two ends of the metal oxide semiconductor layer 09 through two second via holes 132 respectively. The third insulating layer 08 and the fourth insulating layer 10 are both gate insulating layers.

A fifth insulating layer 12 covers the third gate layer 11 and isolates the third gate layer 11 from the planarization layer 15. An OLED anode layer 161 is arranged on the planarization layer 15. The fifth insulating layer 12 is a single-layer silicon oxide (SiOₓ) film.

In this embodiment, the first light-shielding layer 052 and the second light-shielding layer 162 are both located in the second region A2. More specifically, the first light-shielding layer 052 is located on the first insulating layer 04, and the first light-shielding layer 052 is located directly below the metal oxide semiconductor layer 09. A width of the first light-shielding layer 052 and a width of the second light-shielding layer 162 are both greater than a width of the metal oxide semiconductor layer 09, thereby improving the light-shielding performance of both the first light-shielding layer 052 and the second light-shielding layer 162.

The first light-shielding layer 052 is arranged on the first insulating layer 04, and the second insulating layer 06 covers the first light-shielding layer 052 and isolates the first light-shielding layer 052 from the second gate layer 072. The first light-shielding layer 052 and the first gate layer 051 are formed simultaneously through a composition process. More specifically, a metal layer (a material of which is one or a mixture of several of molybdenum and its alloy, chromium and its alloy, aluminum and its alloy, copper and its alloy, and titanium and its alloy) is deposited on and covers the first insulating layer 04. Independent first light-shielding layer 052 and first gate layer 051 are formed using the composition process.

The second light-shielding layer 162 is arranged on the planarization layer 15 and is covered with a pixel definition layer 171. The pixel definition layer 171 is prepared using a polyimide (PI) material. The second light-shielding layer 162 and the OLED anode layer 161 are formed simultaneously through the composition process. The OLED anode layer 161 includes an ITO layer, an AG layer, and an ITO layer which are stacked.

It should be noted that in this embodiment, an OLED, as a light emitting element, includes an OLED cathode layer 19, an OLED luminescent layer 18, and the OLED anode layer 161 which are stacked. The OLED cathode layer 19 includes an Mg metal layer and an AG metal layer which are stacked.

It should be noted that in this embodiment, one end of the source-drain electrode layer 141 of first transistor away from the LTPS layer 03 and one end of the source-drain electrode layer 142 of second transistor away from the metal oxide semiconductor layer 09 are both arranged in the planarization layer 15. The planarization layer 15 is provided with a planarization layer via hole 151, and the OLED anode layer 161 extends into the planarization layer via hole 151 and is in connect with the source-drain electrode layer 141 of first transistor. Through this configuration, the OLED can be electrically connected to the first transistor. Therefore, a bias voltage can be applied to the OLED luminescent layer 18 of the light emitting element through the first transistor, thereby driving the OLED luminescent layer 18 to emit light.

The array substrate provided according to this embodiment can be prepared using the following method, including:

At S1, a chemical vapor deposition (CVD) process is used to deposit a silicon nitride/silicon oxide manufacturing material on the base substrate 01 to form the buffer layer 02.

At S2, an amorphous silicon layer is deposited on the buffer layer 02; an ELA excimer laser technology is used to transform amorphous silicon into polycrystalline silicon; and then a photolithography technique is used to form the LTPS layer 03.

At S3, a silicon nitride layer and a silicon oxide layer are deposited on the LTPS layer 03 in sequence to form the first insulating layer 04, wherein the first insulating layer 04 is used as a polycrystalline silicon gate insulating layer.

At S4, a metal layer (the material of which is one or a mixture of several of molybdenum and its alloy, chromium and its alloy, aluminum and its alloy, copper and its alloy, and titanium and its alloy) is deposited on and covers the first insulating layer 04, and then a photolithography technique is used to form the first gate layer 051 and the first light-shielding layer 052, wherein the first gate layer 051 is used as a gate of a polycrystalline silicon transistor, and the first light-shielding layer 052 is used as a bottom light-shielding layer of the metal oxide semiconductor layer 09.

At S5, a silicon nitride layer and a silicon oxide layer are deposited on the first gate layer 051 and the first light-shielding layer 052 in sequence to form the second insulating layer 06, wherein the second insulating layer 06 is also used as a dielectric layer of a storage capacitor.

At S6, a metal layer (the material of which is one or a mixture of several of molybdenum and its alloy, chromium and its alloy, aluminum and its alloy, copper and its alloy, titanium and its alloy) is deposited on and covers the second insulating layer 06, and then the capacitor upper electrode layer 071 and the second gate layer 072 are formed through the photolithography technique, wherein the second gate layer 072 is used as a bottom-layer gate electrode of the metal oxide semiconductor layer 09, and the capacitor upper electrode layer 071 and the first gate layer 051 respectively constitute an upper electrode and a lower electrode of the storage capacitor.

At S7, a silicon nitride layer and a silicon oxide layer are deposited on the second gate layer 072 and the capacitor upper electrode layer 071 in sequence, thereby forming the third insulating layer 08.

At S8, an indium gallium zinc oxide metal layer is deposited and manufactured on the third insulating layer 08, and the photolithography technique is used to form the metal oxide semiconductor layer 09, wherein the metal oxide semiconductor layer 09 is arranged right above the first light-shielding layer 052.

At S9, a silicon oxide layer is deposited and manufactured on the metal oxide semiconductor layer 09 to form the fourth insulating layer 10.

At S10, a metal layer (the material of which is one or a mixture of several of molybdenum and its alloy, chromium and its alloy, aluminum and its alloy, copper and its alloy, and titanium and its alloy) is deposited on and covers the fourth insulating layer 10, and the third gate layer 11 is formed through the photolithography technique, wherein the third gate layer 11 is used as a top-layer gate electrode of the metal oxide semiconductor layer 09.

At S11, a silicon oxide layer is deposited and manufactured on the third gate layer 11 to form the fifth insulating layer 12.

At S12, after the fifth insulating layer 12 is formed, the fifth insulating layer 12, the fourth insulating layer 10, the third insulating layer 08, the second insulating layer 06, and the first insulating layer 04 are etched to through the photolithography technique to form the run-through first via holes 131 and the run-through second via holes 132, wherein the two first via holes 131 are respectively arranged at the two ends of the upper surface of the LTPS layer 03, and the two second via holes 132 are respectively arranged at the two ends of the upper surface of the metal oxide semiconductor layer 09; bottom orifices of the first via holes 131 are in contact with the upper surface of the LTPS layer 03; and bottom orifices of the second via holes 13 are in contact with the upper surface of the metal oxide semiconductor layer 09.

At S13, a metal (the material of which one or a mixture of several of molybdenum and its alloy, chromium and its alloy, aluminum and its alloy, copper and its alloy, and titanium and its alloy) is deposited inside the first via holes 131 and the second via holes 132; after the first via holes 131 and the second via holes 132 are filled with the metal, orifices of the first via holes 131 away from the LTPS layer 03 and orifices of the second via holes 132 away from the metal oxide semiconductor layer 09 extend out to form a metal layer on the fifth insulating layer 12; and the photolithography technique is performed on the metal layer to form the source-drain electrode layer 141 of first transistor and the source-drain electrode layer 142 of second transistor.

At S14, the source-drain electrode layer 141 of first transistor and the source-drain electrode layer 142 of second transistor are coated with PI to form the planarization layer 15, and the planarization layer via hole 151 is formed by exposure and development, wherein the planarization layer via hole 151 exposes the source-drain electrode layer 141 of first transistor.

At S15, the ITO layer, the AG layer, and the ITO layer are deposited in sequence above the planarization layer 15, and the photolithography technique is used to form the mutually independent OLED anode layer 161 and second light-shielding layer 162, wherein the second light-shielding layer 162 is arranged right above the metal oxide semiconductor layer 09, and the OLED anode layer 161 located in the planarization layer via hole 151 is connected to the source-drain electrode layer 141 of first transistor.

At S16, the OLED anode layer 161 and the second light-shielding layer 162 are coated with the PI, and the pixel definition layer 171 and a supporting column layer 172 are formed after exposure, development, and curing through a halftone mask plate.

At S17, after the above processes are completed on the substrate, the OLED luminescent layer 18 and the OLED cathode layer 19 are deposited on the OLED anode layer 161 in sequence by using an evaporation mask plate through an evaporation method.

At S18, after the OLED luminescent layer 18 and the OLED cathode layer 19 are formed by evaporation, an OLED thin film encapsulation layer 20 is formed through a thin film encapsulation method to isolate the influence of water and oxygen on the OLED device.

In S18, glass encapsulation can be used instead of the thin film encapsulation to form the OLED thin film encapsulation layer 20, thereby isolating the influence of the water and oxygen on the OLED device.

It should be noted that the positions of the source-drain electrode layer 141 of first transistor and the source-drain electrode layer 142 of second transistor in the source diagram of this embodiment are not limited to those shown in the diagram of this embodiment, that is, the specific positions of the source-drain electrode layer 141 of first transistor and the source-drain electrode layer 142 of second transistor can be determined based on a specific circuit design.

It should be noted that the photolithography technique in this embodiment is one process of a patterning technology, and the composition process usually also includes photoresist coating, exposure, development, etching, photoresist peeling, and the like.

In summary, according to the manufacturing method for the array substrate provided according to this embodiment, on the base substrate, the first light-shielding layer 052 is formed after the metal layer that forms the first gate layer 051 is patterned and the second light-shielding layer 162 is formed after the metal layer that forms the OLED anode layer 161 is patterned. The first light-shielding layer 052 and the second light-shielding layer 162 act as light barriers to the metal oxide semiconductor layer 09, which can prevent subsequent light from irradiating the metal oxide semiconductor layer 09, thereby preventing the adverse effects on the transistor characteristics of the second transistor (namely, the oxide-TFT).

Based on the above, the embodiments of the present disclosure further provide a display apparatus, including the array substrate as described above. The display apparatus can be any product or component with a display function, such as a liquid crystal panel, electronic paper, an OLED panel, a mobile phone, a tablet, a TV, a display, a laptop, a digital photo frame, and a navigation device. Correspondingly, the display apparatus also has the same technical effects as the array substrate, and will not be elaborated here.

### Embodiment 2

FIG. 2 is a schematic diagram of an array substrate provided according to an exemplary embodiment of the present disclosure. As shown in FIG. 2, the only difference between the structure of the array substrate provided in this embodiment and the structure of the array substrate in Embodiment 1 is that the second gate layer 072 in the array substrate provided in this embodiment replaces the first light-shielding layer 052 of the array substrate in Embodiment 1 as the first light-shielding layer.

As shown in FIG. 2, the first transistor and the second transistor can be formed on the base substrate 01. In some implementations, the base substrate 01 may be a transparent substrate, such as a glass substrate.

All layers of the first transistor can be formed in sequence. Specifically, a channel layer can be formed on the base substrate 01 first; and a gate insulating layer is then formed. After the gate insulating layer covers the base substrate 01 and the channel layer, the metal layer can be formed on the gate insulating layer 04, and the metal layer is patterned to form a gate electrode of the first transistor. A material of the channel layer can include a crystalline silicon material or an amorphous silicon material, such as monocrystalline silicon, microcrystalline silicon, polycrystalline silicon, a metal oxide, or similar materials. In some implementations, the gate insulating layer may include an inorganic material, such as a silicon oxide (SiOₓ), a silicon nitride (SiNₓ), a composite layer composed of a silicon oxide and a silicon nitride, other suitable dielectric materials, or a combination thereof. In this embodiment, the channel layer is the LTPS layer 03.

As shown in FIG. 2, all layers of the second transistor can be formed in sequence. The second gate layer 072 can be formed on the second insulating layer 06, and the second gate layer 072 is used as a light-shielding layer. Specifically, the metal layer for coverage can be formed on the second insulating layer 06, and the metal layer is patterned to form the capacitor upper electrode layer 071 and the second gate layer 072. The patterning technology includes an exposure process and a development process. In some implementations, the exposure process in the patterning technology can use a halftone mask. The second gate layer 072 is separated from the metal oxide semiconductor layer 09 of the second transistor by the third insulating layer 08, that is, a distance between the second gate layer 072 used as the light-shielding layer and the metal oxide semiconductor layer 09 is affected by the third insulating layer 08. Preferably, a thickness of the third insulating layer 08 can be greater than 0 micrometer and less than or equal to 10 micrometers. In a case that the second gate layer 072 can have a thickness to cover the lower surface of the metal oxide semiconductor layer 09, the degree to which the metal oxide semiconductor layer 09 is covered by the second gate layer 072 can be adjusted by controlling the thickness of the second gate layer 072. Preferably, the thickness of the second gate layer 072 can be between 30 micrometers and 100 micrometers. In some implementations, the second gate layer 072 may be a single-layer structure or a composite layer structure, wherein each layer in the composite layer structure may contain the same material. The composite layer structure is formed by stacking, thereby increasing the thickness of the second gate layer 072.

As shown in FIG. 2, the second light-shielding layer 162 may cover the upper surface of the metal oxide semiconductor layer 09, thereby reducing the chance that the OLED and an external light source irradiate the metal oxide semiconductor layer 09. Furthermore, the lower surface of the metal oxide semiconductor layer 09 is covered by the second gate layer 072, which can reduce the chance that light projected by the base substrate 01 irradiates the metal oxide semiconductor layer 09, thereby avoiding damage caused by external light to the metal oxide semiconductor layer 09.

More specifically, the array substrate provided according to this embodiment can be prepared using the following method, including:

At S1, a chemical vapor deposition (CVD) process is used to deposit a silicon nitride/silicon oxide manufacturing material on the base substrate 01 to form the buffer layer 02.

At S2, an amorphous silicon layer is deposited on the buffer layer 02; an ELA excimer laser technology is used to transform amorphous silicon into polycrystalline silicon; and then a photolithography technique is used to form the LTPS layer 03.

At S3, a silicon nitride layer and a silicon oxide layer are deposited on the LTPS layer 03 in sequence to form the first insulating layer 04, wherein the first insulating layer 04 is used as a polycrystalline silicon gate insulating layer.

At S4, a metal layer (the material of which is one or a mixture of several of molybdenum and its alloy, chromium and its alloy, aluminum and its alloy, copper and its alloy, and titanium and its alloy) is deposited on and covers the first insulating layer 04, and the first gate layer 051 is formed through the photolithography technique.

At S5, a silicon nitride layer and a silicon oxide layer are deposited on the first gate layer 051 in sequence to form the second insulating layer 06, wherein the second insulating layer 06 is also used as a dielectric layer of a storage capacitor.

At S6, a metal layer (the material of which is one or a mixture of several of molybdenum and its alloy, chromium and its alloy, aluminum and its alloy, copper and its alloy, titanium and its alloy) is deposited on and covers the second insulating layer 06, and then the capacitor upper electrode layer 071 and the second gate layer 072 are formed through the photolithography technique, wherein the second gate layer 072 is used as both a bottom-layer gate electrode of the metal oxide semiconductor layer 09 and the first light-shielding layer, and the capacitor upper electrode layer 071 and the first gate layer 051 respectively constitute an upper electrode and a lower electrode of the storage capacitor.

At S7, a silicon nitride layer and a silicon oxide layer are deposited on the second gate layer 072 and the capacitor upper electrode layer 071 in sequence, thereby forming the third insulating layer 08.

At S8, an indium gallium zinc oxide metal layer is deposited and manufactured on the third insulating layer 08, and the photolithography technique is used to form the metal oxide semiconductor layer 09, wherein the metal oxide semiconductor layer 09 is arranged right above the first light-shielding layer 072.

At S9, a silicon oxide layer is deposited and manufactured on the metal oxide semiconductor layer 09 to form the fourth insulating layer 10.

At S10, a silicon oxide layer is deposited and manufactured on the fourth insulating layer 10 to form the fifth insulating layer 12.

At S11, after the fifth insulating layer 12 is formed, the fifth insulating layer 12, the fourth insulating layer 10, the third insulating layer 08, the second insulating layer 06, and the first insulating layer 04 are etched to through the photolithography technique to form the run-through first via holes 131 and the run-through second via holes 132, wherein the two first via holes 131 are respectively arranged at the two ends of the upper surface of the LTPS layer 03, and the two second via holes 132 are respectively arranged at the two ends of the upper surface of the metal oxide semiconductor layer 09; bottom orifices of the first via holes 131 are in contact with the upper surface of the LTPS layer 03; and bottom orifices of the second via holes 13 are in contact with the upper surface of the metal oxide semiconductor layer 09.

At S12, a metal (the material of which one or a mixture of several of molybdenum and its alloy, chromium and its alloy, aluminum and its alloy, copper and its alloy, and titanium and its alloy) is deposited inside the first via holes 131 and the second via holes 132; after the first via holes 131 and the second via holes 132 are filled with the metal, orifices of the first via holes 131 away from the LTPS layer 03 and orifices of the second via holes 132 away from the metal oxide semiconductor layer 09 extend out to form a metal layer on the fifth insulating layer 12; and the photolithography technique is performed on the metal layer to form the source-drain electrode layer 141 of first transistor and the source-drain electrode layer 142 of second transistor.

At S13, the source-drain electrode layer 141 of first transistor and the source-drain electrode layer 142 of second transistor are coated with PI to form the planarization layer 15, and the planarization layer via hole 151 is formed by exposure and development, wherein the planarization layer via hole 151 exposes the source-drain electrode layer 141 of first transistor.

At S14, the ITO layer, the AG layer, and the ITO layer are deposited in sequence above the planarization layer 15, and the photolithography technique is used to form the mutually independent OLED anode layer 161 and second light-shielding layer 162, wherein the second light-shielding layer 162 is arranged right above the metal oxide semiconductor layer 09, and the OLED anode layer 161 located in the planarization layer via hole 151 is connected to the source-drain electrode layer 141 of first transistor.

At S15, the OLED anode layer 161 and the second light-shielding layer 162 are coated with the PI, and the pixel definition layer 171 and a supporting column layer 172 are formed after exposure, development, and curing through a halftone mask plate.

At S16, after the above processes are completed on the substrate, the OLED luminescent layer 18 and the OLED cathode layer 19 are deposited on the OLED anode layer 161 in sequence by using an evaporation mask plate through an evaporation method.

At S17, after the OLED luminescent layer 18 and the OLED cathode layer 19 are formed by evaporation, an OLED thin film encapsulation layer 20 is formed through a thin film encapsulation method to isolate the influence of water and oxygen on the OLED device.

The various technical features in the foregoing embodiments may be randomly combined. For concise description, not all possible combinations of the various technical features in the above embodiments are described. However, provided that combinations of these technical features do not conflict with each other, the combinations of the various technical features are considered as falling within the scope of this specification.

The foregoing embodiments merely express several implementations of the present disclosure. The descriptions thereof are relatively specific and detailed, but are not understood as limitations on the scope of the present disclosure. It should be pointed out that a person of ordinary skill in the art can also make several transformations and improvements without departing from the idea of the present disclosure. These transformations and improvements fall within the protection scope of the present disclosure. Therefore, the protection scope of the patent of the present disclosure shall be subject to the appended claims.

1. An array substrate, comprising:
a base substrate, wherein the base substrate is provided with a first region and a second region which are juxtaposed;
a first transistor, wherein the first transistor is located in the first region and is provided with a first active layer, and the first active layer is low temperature polycrystalline silicon (LTPS);
a second transistor, wherein the second transistor is located in the second region and is provided with a second active layer, and the second active layer is a metal oxide semiconductor;
a first light-shielding layer, wherein the first light-shielding layer is arranged right below the second active layer, and at least an interlayer dielectric layer is arranged between the first light-shielding layer and the second active layer; and
a second light-shielding layer, wherein the second light-shielding layer is arranged right above the second active layer, and a planarization layer and a fifth insulating layer are arranged between the second light-shielding layer and the second active layer.

2. The array substrate according to claim 1, wherein a buffer layer is arranged between the first active layer and an upper surface of the base substrate; the first transistor is further provided with a first gate layer; a first insulating layer is arranged between the first gate layer and an upper surface of the first active layer; and a source-drain electrode layer of the first transistor is electrically connected to two ends of the first active layer through two through holes respectively.

3. The array substrate according to claim 2, wherein the second transistor is further provided with a second gate layer and a third gate layer; a third insulating layer is arranged between the second gate layer and a lower surface of the second active layer; a fourth insulating layer is arranged between the third gate layer and an upper surface of the second active layer; and a source-drain electrode layer of the second transistor is electrically connected to two ends of the second active layer through two through holes.

4. The array substrate according to claim 3, wherein a width of the first light-shielding layer and a width of the second light-shielding layer are not less than a width of the second active layer.

5. The array substrate according to claim 4, wherein the second light-shielding layer is formed by partially etching an organic light emitting diode (OLED) anode layer.

6. The array substrate according to claim 5, wherein the first light-shielding layer is formed by partially etching the first gate layer.

7. The array substrate according to claim 5, wherein the first light-shielding layer is the second gate layer.

8. A method for manufacturing the array substrate according to claim 6, comprising: depositing a metal layer on an upper surface of the first insulating layer; and partially etching the metal layer to obtain the first gate layer located in the first region and the first light-shielding layer located in the second region.

9. A method for manufacturing the array substrate according to claim 7, comprising: depositing a second insulating layer after forming the first gate layer of the first transistor, wherein the second insulating layer further extends to the second region of the base substrate; depositing a metal layer on an upper surface of the second insulating layer; and partially etching the metal layer to obtain a capacitor upper electrode layer located in the first region and the first light-shielding layer located in the second region.

10. A display apparatus, comprising the array substrate according to claim 1.
